(19) United States
(12) Patent Application Publication
(10) Pub. No.: US 2007/0229123 A1
(43) Pub. Date: Oct. 4, 2007

(54) Semiconductor device for microphone applications

(76) Inventor: Chien-Chin Hsiao, Hsin-Chu City (TW)

Correspondence Address: LADAS & PARRY LLP, 224 SOUTH MICHIGAN AVENUE, SUITE 1600, CHICAGO, IL, 60604, US

(21) Appl. No.: 11/393,232

(22) Filed: Mar. 30, 2006

(51) Int. Cl. H03K 3/00

(52) U.S. Cl. 327/111

(57) ABSTRACT

A semiconductor device for microphone applications includes an integrated circuit chip that includes a field-effect transistor, a resistor, a diode, and a capacitor. The field-effect transistor has a source terminal, a drain terminal, and a gate terminal. The resistor has first and second resistor terminals coupled respectively to the source and gate terminals. The diode has anode and cathode terminals coupled respectively to the source and gate terminals. The capacitor has a capacitor terminal that is coupled to the source terminal.

### BACKGROUND OF THE INVENTION

1. Field of the Invention

The invention relates to a semiconductor device, more particularly to a semiconductor device for microphone applications.

2. Description of the Related Art

FIG. 1 illustrates a conventional microphone that includes a capacitive sensor 7, an impedance converter 8, and a filter 9. The capacitive sensor 7 generates an electrical signal that corresponds to a sound wave detected thereby. The impedance converter 8 is coupled to the capacitive sensor 7, and amplifies the electrical signal generated by the capacitive sensor 7. As illustrated in FIG. 2, the impedance converter 8 includes a field-effect transistor (FET) 81, a resistor 83, and a diode 82. The FET 81 has a source terminal, a drain terminal, and a gate terminal. The resistor 83 has first and second resistor terminals connected respectively to the source and gate terminals. The diode 82 has anode and cathode terminals connected respectively to the source and gate terminals. The filter 9 is connected to the impedance converter 8, and filters out noise in the electrical signal generated by the capacitive sensor 7 and amplified by the impedance converter 8.

The aforementioned conventional microphone is disadvantageous in that the impedance converter 8 and the filter 9 include discrete electric components. This results in a relatively large size for the conventional microphone.

### SUMMARY OF THE INVENTION

Therefore, the object of the present invention is to provide a semiconductor device for microphone applications that can reduce the number of discrete electric components used in a microphone.

According to the present invention, a semiconductor device comprises an integrated circuit chip that includes a field-effect transistor, a resistor, a diode, and a capacitor. The field-effect transistor has a source terminal, a drain terminal, and a gate terminal. The resistor has first and second resistor terminals coupled respectively to the source and gate terminals. The diode has anode and cathode terminals coupled respectively to the source and gate terminals. The capacitor has a first capacitor terminal that is coupled to the source terminal, and a second capacitor terminal.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic block diagram of a conventional microphone;

FIG. 2 is a schematic circuit diagram of an impedance converter of the conventional microphone;

FIG. 3 is a schematic circuit diagram of the first preferred embodiment of a semiconductor device for microphone applications according to the present invention;

FIG. 4 is a schematic circuit diagram to illustrate an application of the first preferred embodiment;

FIG. 5 is a schematic view of the second preferred embodiment of a semiconductor device for microphone applications according to the present invention; and

FIG. 6 is a schematic view of the third preferred embodiment of a semiconductor device for microphone applications according to the present invention.

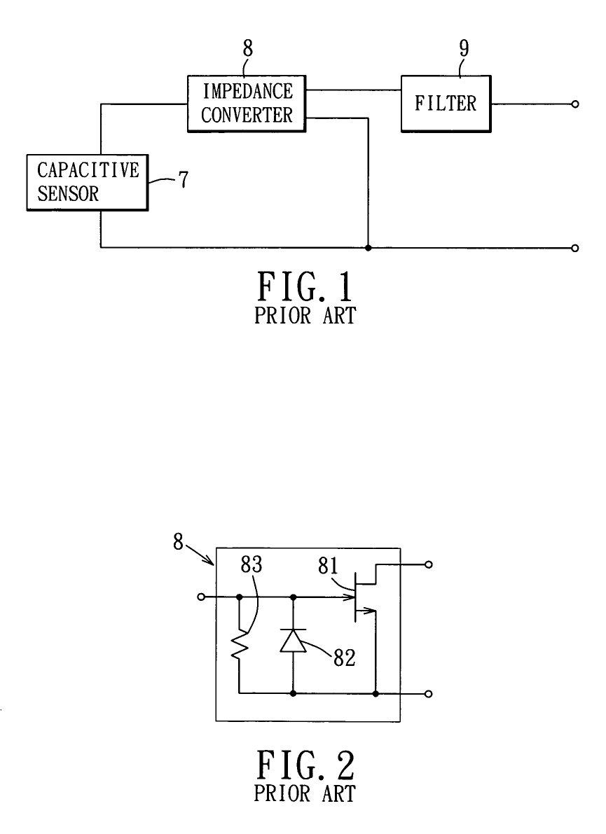

### DETAILED DESCRIPTION OF THE PREFERRED EMBODIMENTS

Before the present invention is described in greater detail, it should be noted that like elements are denoted by the same reference numerals throughout the disclosure.

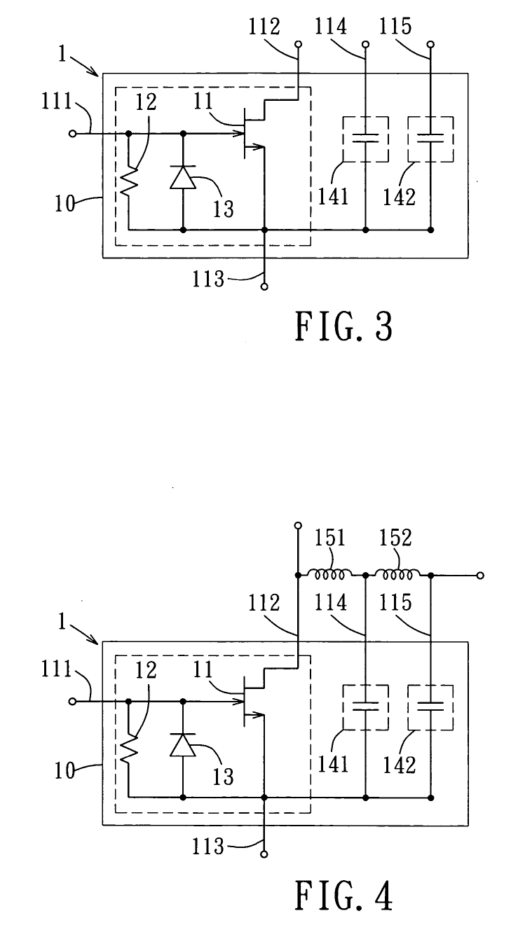

Referring to FIG. 3, the first preferred embodiment of a semiconductor device according to this invention is shown to include an integrated circuit chip 1.

The semiconductor device of this invention is applicable to microphones (not shown).

In this embodiment, the semiconductor device is a packaged semiconductor device.

The integrated circuit chip 1 includes a field-effect transistor (FET) 11, a resistor 12, a diode 13, and first and second capacitors 141, 142. The FET 11 of the integrated circuit chip 1 has a source terminal, a drain terminal, and a gate terminal. The resistor 12 of the integrated circuit chip 1 has first and second resistor terminals connected respectively to the source and gate terminals of the FET 11. The diode 13 of the integrated circuit chip 1 has anode and cathode terminals connected respectively to the source and gate terminals of the FET 11. The first capacitor 141 of the integrated circuit chip 1 has a first capacitor terminal that is connected to the source terminal of the FET 11 of the integrated circuit chip 1, and a second capacitor terminal. The second capacitor 142 of the integrated circuit chip 1 has a first capacitor terminal that is connected to the source terminal of the FET 11 of the integrated circuit chip 1, and a second capacitor terminal.

The semiconductor device further includes an integrated circuit package 10 that encloses the integrated circuit chip 1. In this embodiment, the integrated circuit package 10 is made of epoxy resin.

The semiconductor device further includes a terminal unit. In this embodiment, the terminal unit includes first, second, third, fourth, and fifth external connection terminals 113, 111, 112, 114, 115 that are connected respectively to the source, gate, and drain terminals of the FET 11 of the integrated circuit chip 1 and the second capacitor terminals of the first and second capacitors 141, 142 of the integrated circuit chip 1, and that extend outwardly of the integrated circuit package 10. In this embodiment, each of the first, second, third, fourth, and fifth external connection terminals 113, 111, 112, 114, 115 of the terminal unit is in the form of a metal lead.

It is noted that different filter circuits can be designed for the semiconductor device of this embodiment by connecting electric components, such as inductors, to at least the fourth and fifth external connection terminals 114, 115 of the terminal unit. As an application, the semiconductor device of this embodiment may be applied to implement an LC filter. In particular, referring to FIG. 4, a first inductor 151 is connected between the third and fourth external connection terminals 112, 114 of the terminal unit, and a second inductor 152 is connected between the fourth and fifth external connection terminals 114, 115 of the terminal unit. In this application, the third and first external connection terminals 112, 113 of the terminal unit are connected to a voltage supply (not shown) and aground (not shown), respectively. Moreover, a filtered output signal is provided across the fifth and first external connection terminals 115, 113 of the terminal unit.

Although the semiconductor device of this embodiment is applied to implement an LC filter, it should be apparent to those skilled in the art that an RC filter may be implemented instead.

In an alternative embodiment, the integrated circuit chip 1 is dispensed with the second capacitor 142, the terminal unit is dispensed with the fifth external connection terminal 115, and the semiconductor device may be applied to implement an LC filter by connecting an inductor between the third and fourth external connection terminals 112, 114 of the terminal unit.

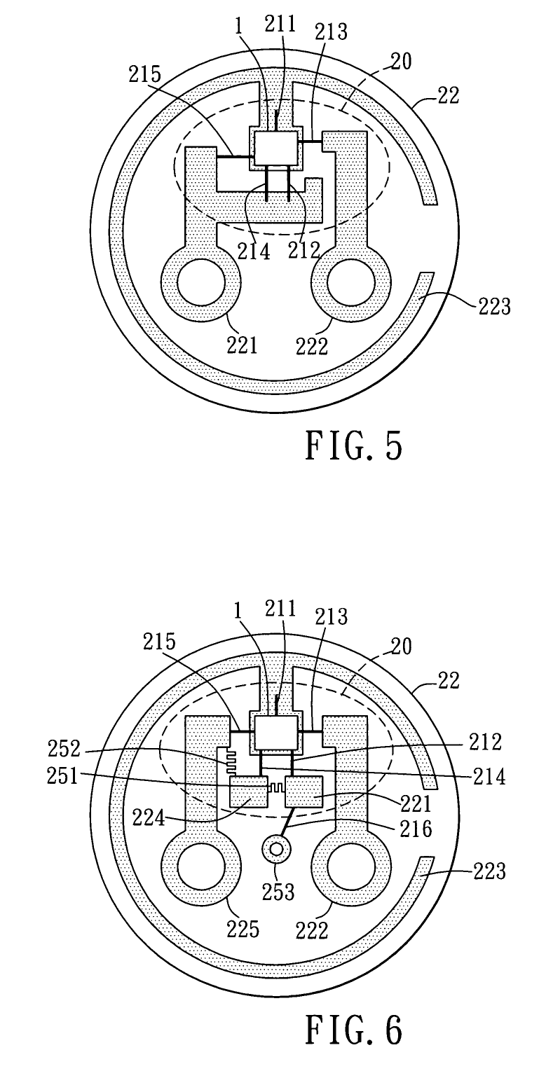

FIG. 5 illustrates the second preferred embodiment of a semiconductor device according to this invention.

In this embodiment, the semiconductor device is a chip-on-board (COB) package.

When compared with the previous embodiment, the semiconductor device further includes a circuit board 22, and the integrated circuit chip 1 is mounted directly on the circuit board 22. The circuit board 22 is formed with a circuit trace unit that includes first, second and third circuit traces 222, 223, 221.

The semiconductor device further includes a wire unit, instead of the terminal unit of the previous embodiment. The wire unit includes first, second, third, fourth and fifth bonding wires 213, 211, 212, 214, 215. The first, second and third bonding wires 213, 211, 212 of the wire unit couple the source, gate and drain terminals of the FET 11 of the integrated circuit chip 1 to the first, second and third circuit traces 222, 223, 221 of the circuit trace unit, respectively. In this embodiment, the fourth and fifth bonding wires 214, 215 of the wire unit couple the second capacitor terminals of the first and second capacitors 141, 142 of the integrated circuit chip 1 to the third circuit trace 221 of the circuit trace unit, respectively.

The semiconductor device further includes a sealant 20 that covers the integrated circuit chip 1 and the wire unit on the circuit board 22. In this embodiment, the sealant 20 is made of epoxy resin.

FIG. 6 illustrates the third preferred embodiment of a semiconductor device according to this invention.

In this embodiment, the semiconductor device, like the second embodiment, is a chip-on-board (COB) package.

When compared with the second embodiment, the circuit trace unit further includes fourth and fifth circuit traces 224, 225. The fourth and fifth bonding wires 214, 215 of the wire unit couple the second capacitor terminals of the first and second capacitors 141, 142 of the integrated circuit chip 1 to the fourth and fifth circuit traces 224, 225 of the circuit trace unit, respectively, instead of to the third circuit trace 221 of the circuit trace unit.

The semiconductor device further includes a first electric component 251 connected between the third and fourth circuit traces 221, 224 of the circuit trace unit, and a second electric component 252 connected between the fourth and fifth circuit traces 224, 225 of the circuit trace unit. In this embodiment, each of the first and second electric components 251, 252 is a tortuous inductor trace formed on the circuit board 22.

The circuit trace unit further includes a sixth circuit trace 253. The wire unit further includes a sixth bonding wire 216 that couples the third circuit trace 221 of the circuit trace unit to the sixth circuit trace 253 of the circuit trace unit.

In an application of the semiconductor device of this embodiment, the sixth circuit trace 253 of the circuit trace unit is connected to the voltage supply (not shown). The first circuit trace 222 of the circuit trace unit is connected to the ground (not shown). The filtered output signal is provided across the fifth and third circuit traces 225, 222 of the circuit trace unit.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A semiconductor device comprising:
an integrated circuit chip including
a field-effect transistor having a source terminal, a drain terminal, and a gate terminal,
a resistor having first and second resistor terminals coupled respectively to said source and gate terminals,
a diode having anode and cathode terminals coupled respectively to said source and gate terminals, and
a first capacitor having a first capacitor terminal that is coupled to said source terminal, and a second capacitor terminal.

2. The semiconductor device as claimed in claim 1, further comprising an integrated circuit package that encloses said integrated circuit chip.

3. The semiconductor device as claimed in claim 2, further comprising a terminal unit including first, second, third and fourth external connection terminals that are coupled respectively to said source, gate, and drain terminals of said field-effect transistor and said second capacitor terminal of said first capacitor, and that extend outwardly of said integrated circuit package.

4. The semiconductor device as claimed in claim 3, wherein:
said integrated circuit chip further includes a second capacitor that has first and second capacitor terminals, said first capacitor terminal of said second capacitor being coupled to said source terminal; and
said terminal unit further includes a fifth external connection terminal that is coupled to said second capacitor terminal of said second capacitor and that extends outwardly of said integrated circuit package.

5. The semiconductor device as claimed in claim 3, wherein said integrated circuit package is made of epoxy resin.

6. The semiconductor device as claimed in claim 3, wherein each of said first, second, third and fourth external connection terminals is in the form of a metal lead.

7. The semiconductor device as claimed in claim 1, further comprising a circuit board having said integrated circuit chip mounted thereon.

8. The semiconductor device as claimed in claim 7, wherein:
said circuit board is formed with a circuit trace unit that includes first, second and third circuit traces;
said semiconductor device further comprising a wire unit that includes first, second and third bonding wires for coupling said source terminal, said gate terminal and said drain terminal to said first, second and third circuit traces, respectively.

9. The semiconductor device as claimed in claim 8, wherein said integrated circuit chip further includes a second capacitor that has first and second capacitor terminals, said first capacitor terminal of said second capacitor being coupled to said source terminal.

10. The semiconductor device as claimed in claim 9, wherein said wire unit further includes fourth and fifth bonding wires for coupling said second capacitor terminals of said first and second capacitors to said third circuit trace, respectively.

11. The semiconductor device as claimed in claim 9, wherein said circuit trace unit further includes fourth and fifth circuit traces, and said wire unit further includes fourth and fifth bonding wires for coupling said second capacitor terminals of said first and second capacitors to said fourth and fifth circuit traces, respectively.

12. The semiconductor device as claimed in claim 11, further comprising:
a first electric component coupled between said third and fourth circuit traces; and
a second electric component coupled between said fourth and fifth circuit traces.

13. The semiconductor device as claimed in claim 12, wherein at least one of said first and second electric components is a tortuous inductor trace formed on said circuit board.

14. The semiconductor device as claimed in claim 12, wherein said circuit trace unit further includes a sixth circuit trace, and said wire unit further includes a sixth bonding wire for coupling said third circuit trace to said sixth circuit trace.

15. The semiconductor device as claimed in claim 8, further comprising a sealant that covers said integrated circuit chip and said wire unit on said circuit board.

16. The semiconductor device as claimed in claim 15, wherein said sealant is made of epoxy resin.
